(19) United States
(12) Patent Application Publication
(10) Pub. No.: US 2024/0385541 A1
(43) Pub. Date: Nov. 21, 2024

(54) EUV LITHOGRAPHY SYSTEM HAVING A GAS-BINDING COMPONENT

(71) Applicants: Carl Zeiss SMT GmbH, Oberkochen (DE); ASML Netherlands B.V., Veldhoven (NL)

(72) Inventors: Wilbert KRUITHOF, Pleinfeld (DE); Parham YAGHOOBI, Veldhoven (NL); John LEO, Veldhoven (NL)

(21) Appl. No.: 18/790,520

(22) Filed: Jul. 31, 2024

Related U.S. Application Data
(63) Continuation of application No. PCT/EP2022/086038, filed on Dec. 15, 2022.

(30) Foreign Application Priority Data
Feb. 2, 2022 (DE) 10 2022 102 478.4

(51) Int. Cl. G03F 7/00

(52) U.S. Cl. CPC G03F 7/70916; G03F 7/70033; G03F 7/702; G03F 7/70233

(57) ABSTRACT

A lithography system for extreme ultraviolet (EUV) radiation includes a housing (25) with an interior (24) containing a residual gas (27), and at least one gas-binding component (29) which is arranged in the interior (24) and has a gas-binding material for binding contaminating substances (28). The gas-binding component (29) has at least one flow duct (33) having at least one surface with the gas-binding material, with a gas flow of the residual gas (27) in the flow duct (33) having a Knudsen number of between 0.01 and 5, preferably between 0.01 and 0.5, in particular between 0.01 and 0.3, and with a casing (26) which encapsulates a beam path of the EUV lithography system (1) being arranged in the interior (24) of the housing (25). The casing (26) preferably has an opening (37) with a maintenance shaft (36) in which the gas-binding component (29) is arranged.

### CROSS-REFERENCE TO RELATED APPLICATION

This is a Continuation of International Application PCT/EP2022/086038, which has an international filing date of Dec. 15, 2022, and the disclosure of which is incorporated in its entirety into the present Continuation by reference. This Continuation also claims foreign priority under 35 U.S.C. § 119 (a)-(d) to and also incorporates by reference, in its entirety, German Patent Application DE102022102478.4 filed Feb. 2,2022.

### FIELD

The invention relates to an extreme ultraviolet (EUV) lithography system comprising: a housing having an interior that contains a residual gas and at least one gas-binding component which is arranged in the interior and which comprises a gas-binding material for binding contaminating substances.

### BACKGROUND

For the purposes of this application, an EUV lithography system is understood to mean an optical system that can be used in the field of EUV lithography. In addition to a projection exposure apparatus for EUV lithography which serves for production of semiconductor components, the lithography system may, for example, be an inspection system for inspection of a photomask used in such a projection exposure apparatus (also referred to hereinafter as reticle), for inspection of a semiconductor substrate to be structured (also referred to hereinafter as wafer), or a metrology system which is used for measurement of a projection exposure apparatus for EUV lithography or parts thereof, for example for measurement of a projection optical unit.

In order to achieve the smallest possible structure width for the semiconductor components to be produced, state-of-the-art projection exposure apparatuses, also known as EUV lithography apparatuses, are designed for an operating wavelength in the extreme ultraviolet (EUV) wavelength range, i.e., within a range from about 5 nm to about 30 nm. Since wavelengths in this range are strongly absorbed by just about all materials, it is typically not possible to use transmissive optical elements. Use of reflective optical elements is required. Such optical elements that reflect EUV radiation may, for example, be mirrors, reflective monochromators, collimators or photomasks. Since EUV radiation is also strongly absorbed by air molecules, the beam path of the EUV radiation is arranged within a vacuum environment.

In EUV lithography apparatuses, contaminating substances present in the vacuum environment (also called contaminations hereinafter) lead to a reduction in the reflection of the mirrors and hence to a reduction in the optical performance, the system transmission and the system throughput (the number of wafers per hour). As well as contaminations in the form of hydrocarbons, the outgassing of contaminations in the form of harmful chemical elements or compounds from components disposed in the vacuum environment leads to degradation of the mirrors. The harmful chemical elements or compounds may, for example, be hydrogen-volatile elements or compounds (HIO=“hydrogen induced outgassing”), for example compounds containing phosphorus, zinc, tin, sulfur, indium, magnesium or silicon. Sn, in particular, can be present in the vacuum environment in the form of droplets which move through the EUV lithography apparatus by virtue of ricocheting off the EUV mirrors.

In the context of analyses, it was found that one possible cause of the mirror contamination lies in the coverage of surfaces of the mechanical (i.e., non-optical) components installed in the vicinity of the mirror with contaminants including HIO elements or compounds that are redistributed from the surfaces of these components onto the surfaces of the mirrors under operating conditions.

It is known to arrange gas-binding components having at least one surface composed of a gas-binding material in the vacuum environment with the mirrors, in order to chemically bind or retain the contaminating substances, especially the HIO compounds, in order thus to prevent, weaken or delay the adsorption thereof on the surfaces of the mirrors.

U.S. Pat. No. 7,473,908B2 discloses a lithography apparatus comprising an object having a first surface designed to bind metallic contaminations, e.g., metals, metal oxides, metal hydroxides, metal hydrides, metal halides and/or metal oxyhalides of the elements Sn, Mn and/or Zn. The first surface may have a metallic surface, with the metal selected from the group comprising: Ru, Rh, Pd, Ag, Re, Os, Ir, Pt and/or Au.

DE 10 2014 204 658 A1 describes an optical arrangement having a casing with at least one component arranged therein that outgases contaminating substances on contact with activated hydrogen. An opening duct connects the component to a vacuum chamber with at least one optical element disposed therein. The inner wall of the opening duct may have a coating for reduction of the exit rate of the contaminating substances that contains a material selected from the group comprising: Rh, Ru, Ir, Pt, Ti, Ni, Pd and compounds thereof. For reduction of the entry rate of the activated hydrogen, the coating may contain a material selected from the group comprising: Rh, Ru, Ir, Pt, Ti, Ni, Pd, Al, Cu, Fe and compounds thereof.

US 2020/0166847 A1 describes an optical arrangement for EUV lithography which comprises at least one reflective optical element having a main body with a coating that reflects EUV radiation. At least one shield is fitted to at least one surface region of the main body and protects the surface region against an etching effect of a plasma surrounding the reflective optical element during operation of the optical arrangement. The material of the shield may be selected from the group comprising: metallic materials, especially Cu, Co, Pt, Ir, Pd, Ru, Al, stainless steel, and ceramic materials, especially AlOₓ, Al₂O₃. The shield or cover may consist of a hydrogen recombination material or include a hydrogen recombination material. The hydrogen recombination material may serve as contamination getter material, for example when it is selected from the group comprising: Ir, Ru, Pt, Pd.

U.S. Pat. Nos. 8,382,301 B2 and 8,585,224 B2 describe a projection exposure apparatus for EUV lithography that has a housing with at least one optical element arranged therein. Also arranged in the housing is at least one vacuum housing or a casing that surrounds at least the optical surface of the optical element. In one example, the vacuum housing serves as contamination reduction unit and consists of a gas-binding material on its inner face at least in one subregion.

US 2006/0221440 A1 describes a spectral cleaning filter having a multilayer structure with alternating layers in order to increase the spectral purity of radiation passing through the spectral cleaning filter. The spectral cleaning filter is also designed to collect contaminations emitted by a light source. The multilayer structure can be supported by a mesh-like structure or the mesh-like structure can be embedded in the multilayer structure. The mesh-like structure can be in the form of honeycombs and have a plurality of openings.

A problem with the use of a gas-binding component for binding contaminating substances lies in the fact that the surface area of the surface(s) with the gas-binding material should be significantly larger than the optical surfaces of the EUV mirrors in order to effectively suppress the accumulation of contaminations on the optical surfaces. However, for reasons of installation space, the volume available to the gas-binding component cannot be increased as desired. Moreover, the gas-binding effect of the gas-binding material reduces as the amount of contaminating substances bound to the surface of the component increases, and so the gas-binding component must typically be replaced after a certain amount of time.

### SUMMARY

One object of the invention involves providing an EUV lithography system having at least one gas-binding component which uses the available installation space to more efficiently bind contaminating substances than heretofore known.

This and other objects are achieved by an EUV lithography system of the type set forth at the outset, wherein the gas-binding component comprises at least one flow duct having at least one surface with the gas-binding material, with a gas flow of the residual gas in the flow duct having a Knudsen number of between 0.01 and 5, preferably between 0.01 and 0.5, in particular between 0.01 and 0.3. The gas-binding material serves to bind contaminating substances present in the gas phase and/or to bind contaminating substances, e.g., in the form of droplets or the like located in the vacuum environment.

As described, e.g., in “https://www.pfeiffer-vacuum.com/en/know-how/introduction-to-vacuum-technology/fundamentals/types-of-flow/”, the Knudsen number Kn is defined as the ratio of mean free path length l̅ of the gas particles to the flow width h of the flow duct, i.e.,

$$K n = \frac{\overline{l}}{h} .$$

The Knudsen number is dimensionless and characterizes the type of gas flow through the flow duct. A Knudsen number Kn of less than 0.01 indicates a continuum flow, in which there are frequent collisions between the gas particles themselves but fewer collisions with the walls of the flow duct. In this case, the mean free path length is significantly shorter than the dimensions of the flow duct. A Knudsen number Kn in the value range stated further above indicates a Knudsen flow. The Knudsen flow represents a transition region between continuum flow and molecular flow at a Knudsen number Kn of more than 5, which is typically present in high vacuum and in ultrahigh vacuum. There is practically no more interaction between the particles in the case of a Knudsen number Kn of more than 5, i.e., the mean free path length is significantly longer than the flow width of the flow duct.

The inventors have recognized that an installation space volume available to the gas-binding component can be utilized advantageously if the gas-binding component has one or more flow ducts in which the Knudsen number is in the aforementioned value range, i.e., in which a Knudsen flow is present in the flow duct, to be precise for the following reason: Although the gas flow penetrates far into the flow duct on account of diffusion in the case of a continuum flow, there are only few collisions with the walls of the flow duct. Knudsen flow provides sufficient diffusion for the gas flow of the residual gas to penetrate deeply into the flow duct, and there are sufficient interactions with the walls of the flow duct so that the contaminating substances can be adsorbed by the gas-binding material on the walls or on the surfaces of the flow duct. The gas-binding component thus acts in the style of an atomic trap for the contaminating substances, which enter the flow duct and are bound by the gas-binding material.

The Knudsen flow in the flow duct or ducts allows provision of a large surface in relation to the installation space volume provided for the gas-binding component for the gas-binding material. This can ensure that the gas-binding component generally maintains its gas-binding effect over the entire service life of the EUV lithography system. Moreover the Knudsen flow means that the increase of the surface does not lead to a reduction in the efficiency since the residual gas, and hence also the contaminating substances, are both able to penetrate sufficiently deeply into the flow duct and also able to undergo a large number of collisions or interactions with the walls of the flow duct. In the design of the EUV lithography system, the gas flow through the interior of the housing should ideally be optimized for the flow through the flow duct or ducts of the gas-binding component.

In an embodiment, the residual gas in the interior of the housing has a pressure of between 1 Pa and 20 Pa, preferably between 2 Pa and 12 Pa. During the operation of an EUV lithography system, such pressures typically prevail in a respective interior of a housing, with the pressure value possibly varying across different positions in the EUV lithography apparatus.

The following formula applies to the product of mean free path length l̅ and the pressure p of an ideal gas satisfying the Boltzmann distribution:

$$\overline{l} p = \frac{{k}_{B} T}{\sqrt{2} π {d}_{m}^{2}}$$

where k_{B} denotes the Boltzmann constant, T denotes the temperature (in K) and dₘ denotes the diameter of the gas molecules. In the case of an ideal gas with a specified molecular diameter dₘ, the mean free path length l̅ thus depends only on the temperature T and the pressure p. As a rule, the residual gas in the interior of an EUV lithography system housing contains only a very small proportion of contaminating substances but has a comparatively large proportion of hydrogen. The pressure p of the residual gas in the interior is therefore determined by the hydrogen partial pressure, or the pressure p in the interior essentially corresponds to the hydrogen partial pressure. Hydrogen has a molecular diameter dₘ of approx. 2.76 Angstrom. At a temperature T of 22° C. (room temperature), the product l̅p=12 mm Pa arises for hydrogen. For example, the mean free path length l̅ is therefore approximately 2.4 mm for a pressure p of 5 Pa. To create a Knudsen flow in the flow duct, the flow width (see below) should be of the same order of magnitude.

In an embodiment, the flow duct has a flow width of between 1 mm and 30 mm, preferably between 4 mm and 20 mm. The flow width of the flow duct is understood to mean a characteristic length of the flow field of the flow duct. For a flow duct with a circular cross section, the flow width of the flow duct is the diameter of the flow duct, for example.

In a further embodiment, the flow duct comprises two opposing surfaces which are preferably aligned in parallel, the surfaces each having the gas-binding material, with a distance between the opposing surfaces defining the flow width of the flow duct. In this case, the flow duct does not have a round flow cross section. Therefore, the distance between the two opposing surfaces is used to calculate the Knudsen number. For the parallel alignment of the two surfaces, the width or the spacing between the two surfaces in the longitudinal direction of the flow duct is constant. However, such a parallel alignment is not mandatory, i.e., the width of the flow duct may optionally vary in the longitudinal direction of the flow duct provided the condition described further above in relation to the Knudsen number is observed in this case.

In a development of this embodiment, the two opposing surfaces are formed on two planar component portions which are preferably aligned in parallel. In this case, the flow duct is generally open to the side, i.e., the flow duct typically does not have a closed cross section in the circumferential direction. In this case, the flow duct extends between the two planar component portions, at the lateral edges of which residual gas can flow into the flow duct. Especially for the case of a parallel alignment of the planar component portions, it is possible to arrange or stack a plurality of planar component portions one above the other in order to form a plurality of flow ducts aligned in parallel.

The gas-binding material may be applied to the surface of the component portions in different ways, for example in the form of a coating; however, it is also possible that the component portions themselves consist of a gas-binding material.

In a further embodiment, the planar component portions are formed as sheets or as films. Sheets are cantilevered components which can be fitted on one side to a mount of the gas-binding component or the gas-binding module, and which are optionally supported by support struts. The mount on one side facilitates the inflow of the residual gas into the flow ducts at the free ends of the sheets not accommodated by the mount. Depending on the number and dimension of the sheets, the gas-binding component might have a significant weight. For example, the sheet material can be stainless steel or aluminum. Since stainless steel has greater stiffness than aluminum while having a similar specific weight, sheets of stainless steel are generally better suited to the production of a planar component portion than sheets of aluminum.

If the component portions are non-cantilevered elements in the form of films, then these films are typically spanned between two mounts fitted to opposite ends of the films. To allow the residual gas to flow into the flow ducts, the latter may optionally have holes or perforations should a lateral residual gas inflow be impossible or only possible with difficulties on account of a limited installation space, for example on account of the proximity of the gas-binding component to a wall or the like. The use of films is advantageous especially for reducing the weight of the gas-binding component.

In an alternative embodiment, the flow duct has a cross section in the form of a regular polygon, in particular a regular hexagon. The flow duct is closed in the circumferential direction in this embodiment. For the gas-binding component, a multiplicity of flow ducts are in this case typically arranged next to one another in the style of a grid in a three-dimensional structure. Adjacent flow ducts in the grid may directly adjoin one another, especially in the event of the cross-sectional shape of the flow ducts being a regular hexagon. In this way, the entire surface covered by the front side of the grid or the entire volume of the gas-binding component can be filled with flow ducts. Compared to the embodiment described further above with the planar component portions, the surface with the gas-binding material available for a given installation space volume thus can be increased further for the embodiment described here. However, this case removes the option of lateral inflow of the residual gas into a respective flow duct.

In a further embodiment, the gas-binding component has a plurality of flow ducts with differently dimensioned flow widths for binding different contaminating substances. It may be advantageous for the flow ducts to have different flow widths since different contaminating substances have a different effective cross section when interacting or colliding with the residual gas, more precisely with the hydrogen contained in the latter. For example, it is possible to arrange a number of, e.g., approx. 10 or approx. 20 planar component portions, e.g., in the form of sheets, one above the other with parallel alignment and in the process use two, three or more different flow widths or spacings between adjacent sheets, for example. In this context, a second flow width may correspond for example to twice the first flow width, and a third flow width may correspond to twice the second flow width. It is understood that the flow widths can also be chosen differently to the way described here.

The flow width can also be varied in the case of one component which comprises a plurality of flow ducts in the form of regular polygons. For example, a plurality of grids with regular polygons can be arranged one behind the other in the longitudinal direction of the flow ducts in this case, with the flow width or the dimension of the polygons in a respective grid being chosen differently. In particular, the flow width of grids with further upstream polygons in the flow direction can be chosen in this case to be larger than the flow width of grids with further downstream polygons in the flow direction.

In a further embodiment, the flow duct has a length of at least 20 cm, preferably at least 40 cm. As has been described further above, the surface of the gas-binding material should be as large as possible. It is thus advantageous for the flow duct to have a comparatively long length. It is possible to configure the design of the EUV lithography system such that a sufficient volume is available for the gas-binding component. Especially in the case where the gas-binding component is retrofitted to an EUV lithography system already in operation, it is advantageous for the gas-binding component to form a compact module which efficiently binds the gas-binding contaminating substances. In this case, the length of the flow ducts should optionally be chosen to be not too long. In the case where the gas-binding component comprises the planar component portions described further above, it is generally advantageous for the width of the planar component portions to substantially correspond to the length of the flow ducts, i.e., for the planar component portions to have a rectangular, almost square geometry.

In a further embodiment, the gas-binding material is selected from the group comprising: Ru, Ni, NiP, Rd, Rh, Ta, Nb, Ti, Zr, Th and the compounds thereof. The adsorption properties with respect to the contaminating substances of the gas-binding material or materials should be comparable or better to those of the materials in the capping layer of a reflective coating of an EUV mirror (for example Ru, RuO, RuO₂, ZrO₂, ZrO, . . . ).

The gas-binding material used is generally a metal or an alloy that binds the contaminating substances by adsorption, chemisorption or chemical reaction. The gas particles of the contaminating substances adsorbed on the surface of the gas-binding material diffuse rapidly into the interior of the gas-binding material and make room for further gas particles that hit the surface. The abovementioned materials and possibly other materials enable binding of the contaminating substances or a majority of types thereof, for example in the form of Si, Mg, etc., which are present in the EUV lithography system.

In principle, the gas-binding component can be arranged at any desired location in the EUV lithography system. However, it is advantageous if the gas-binding component is arranged in the vicinity of a source of the gas-binding contaminating substances and/or in the vicinity of the optical units, i.e., in the vicinity of a surface of a reflective optical element. The gas-binding component is typically arranged outside of the beam path of the EUV lithography system.

In a further embodiment, at least one reflective optical element is arranged in the interior of the housing, and the gas-binding component is arranged adjacent to a surface of the reflective optical element and preferably surrounds a surface of the optical element at least in part. In the embodiment described further above, the gas-binding component can be fitted adjacent to the surface of the reflective optical element, e.g., to an optical element mount. It is likewise possible for the gas-binding component to completely (in ring-shaped fashion) surround the beam path or the surface of the reflective optical element in the circumferential direction or to extend only along a portion of the outer contour of the surface of the optical element in the circumferential direction.

In a further embodiment, a casing which encapsulates a beam path of the EUV lithography system is arranged in the interior of the housing, the casing preferably comprising an opening with a maintenance shaft in which the gas-binding component is arranged. The casing which encapsulates the beam path serves to reduce the concentration of contaminating substances within the casing vis-à-vis the casing surroundings. The arrangement of gas-binding components within the casing is advantageous as a matter of principle since components arranged within the casing, e.g., force frames or the like, also potentially contain materials that outgas contaminating substances. However, retrofitting gas-binding components into the casing(s) of already existing EUV lithography systems is generally not possible without significant outlay.

An advantageous option of arranging the gas-binding component in the casing consists of arranging said gas-binding component in a maintenance shaft of the casing which is generally closed off by a cover or a door following the completion of the maintenance. In this case, the gas-binding component can be placed on the floor of the maintenance shaft or optionally be fastened to the cover or the door serving to close off the maintenance shaft. The gas-binding component can easily be retrofitted by way of the maintenance shaft, even in the case of EUV lithography systems that have already been delivered. The arrangement in the maintenance shaft also allows simple exchange of the gas-binding component should this be required if the effect of the gas-binding material drops off over the service life of the EUV lithography system. It is understood that the gas-binding component can also be arranged at other positions in the EUV lithography system that allow a particularly simple exchange.

As has been described further above, the gas-binding component advantageously has a weight-adjusted geometry, especially for the case in which it should be exchanged. For example, this can be achieved by virtue of the component comprising the planar component portions described further above or possibly differently shaped component portions or substructures made of a film. In particular, support structures or the like can also be covered by a thin film coated with the gas-binding material.

In a further embodiment, the at least one surface with the gas-binding material is structured. The surface with the gas-binding material can be structured, e.g., by roughening or by any other type of substructure, in order to increase the effective surface and/or increase the capture probability for the contaminating substances. Should the gas-binding material be applied to the surface in the form of a coating, the surface can be structured before or optionally after the deposition of the coating. The structure dimensions of the structures used during the surface structuring should be of the order of the mean free path length l̅ or smaller.

Further features and advantages of the invention are evident from the following description of exemplary embodiments of the invention, with reference to the figures of the drawing, which show details associated with the invention, and from the claims. The individual features can each be implemented individually or together in in accordance with further aspects of the invention.

### BRIEF DESCRIPTION OF THE DRAWINGS

Exemplary embodiments are shown in the schematic drawing and are explained in the description which follows. In the figures:

FIG. 1 schematically shows a meridional section of a projection exposure apparatus for EUV projection lithography,

FIG. 2 shows a schematic illustration of a casing in which two facet mirrors and a plurality of gas-binding components have been fitted,

FIGS. 3A and 3B show schematic illustrations of gas-binding components with stacked sheets (FIG. 3A) or films (FIG. 3B) that have flow ducts formed therebetween, in which a Knudsen flow prevails during the operation of the projection exposure apparatus,

FIGS. 4A-4C show schematic illustrations of a gas flow in the form of a continuum flow (FIG. 4A), a Knudsen flow (FIG. 4B) and a molecular flow (FIG. 4C) through a flow duct,

FIG. 5 shows a schematic illustration of the dimensions of a stack of sheets with three different flow widths of the flow ducts, and

FIG. 6 shows a schematic illustration of a plan view of an optical surface of one of the facet mirrors in FIG. 2 with a gas-binding component which surrounds the optical surface and comprises flow ducts in the style of honeycombs.

### DETAILED DESCRIPTION

In the description of the drawings that follows, identical reference signs are used for components that are the same or analogous or have the same or analogous function.

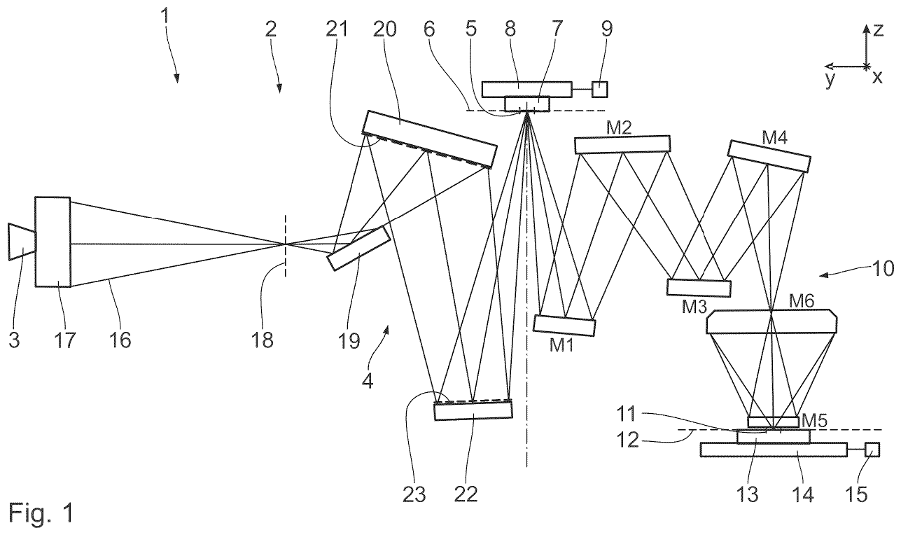

There follows a description with reference to FIG. 1 by way of example of the salient constituents of an optical arrangement for EUV lithography in the form of a projection exposure apparatus 1 for microlithography. The description of the basic setup of the projection exposure apparatus 1 and the constituent parts thereof should not be considered here to be restrictive.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided in the form of a module separate from the rest of the illumination system. In this case, the illumination system does not include the light source 3.

A reticle 7 arranged in the object field 5 is illuminated. The reticle 7 is held by a reticle holder 8. The reticle holder 8 is displaceable, in particular in a scanning direction, by way of a reticle displacement drive 9.

For explanation purposes, a Cartesian xyz-coordinate system is depicted in FIG. 1. The x-direction runs perpendicularly into the plane of the drawing. The y-direction runs horizontally, and the z-direction runs vertically. The scanning direction runs along the y-direction in FIG. 1. The z-direction runs perpendicular to the object plane 6.

The projection exposure apparatus 1 comprises a projection system 10. The projection system 10 is used to image the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction. The displacement firstly of the reticle 7 with the reticle displacement drive 9 and secondly of the wafer 13 with the wafer displacement drive 15 may be mutually synchronized.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 can be incident on the at least one reflection surface of the collector mirror 17 with grazing incidence (GI), i.e., at angles of incidence of greater than 45°, or with normal incidence (NI), i.e., at angles of incidence of less than 45°. The collector mirror 17 can be structured and/or coated, firstly, for adjusting its reflectivity for the used radiation and, secondly, for suppressing extraneous light.

Downstream of the collector mirror 17, the illumination radiation 16 propagates through an intermediate focus in an intermediate focal plane 18. The intermediate focal plane 18 can constitute a separation between a radiation source module, comprising the radiation source 3 and the collector mirror 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. In an alternative to that or in addition, the deflection mirror 19 may be designed as a spectral filter that separates a used light wavelength of the illumination radiation 16 from extraneous light at a different wavelength. The first facet mirror 20 comprises a multiplicity of individual first facets 21, which are also referred to below as field facets. FIG. 1 illustrates only some of said facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 consequently forms a doubly faceted system. This fundamental principle is also referred to as a fly's eye integrator. With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optical unit 10 has an image-side numerical aperture which is greater than 0.4 or 0.5 and which can also be greater than 0.6 and which can be for example 0.7 or 0.75.

Just like the mirrors of the illumination optical unit 4, the mirrors Mi can have a highly reflective coating for the illumination radiation 16.

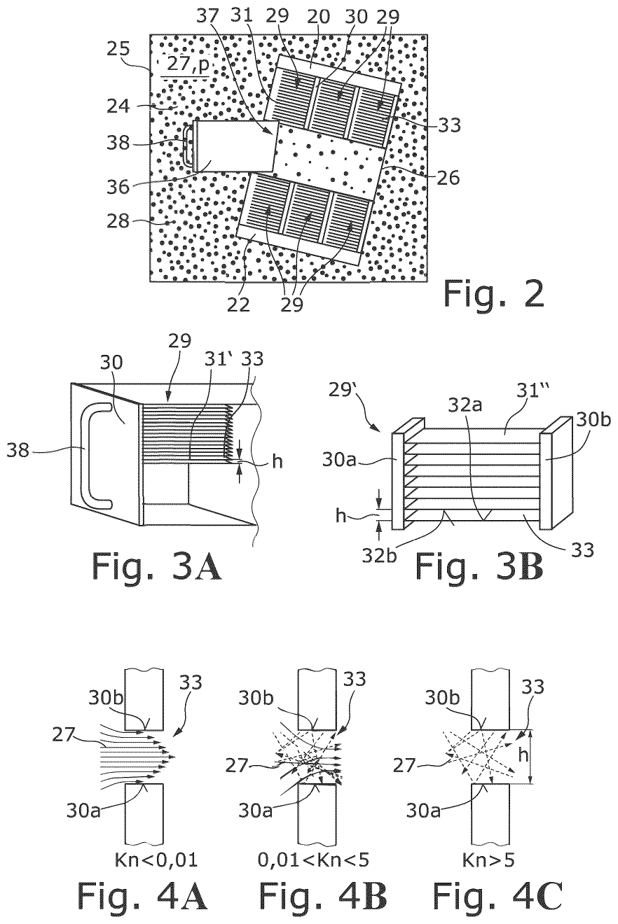

The illumination optical unit 4 as a whole is arranged in an interior 24 of a housing 25 shown in FIG. 2, in which a vacuum environment is created with the aid of a vacuum pump (not depicted pictorially) during the operation of the projection exposure apparatus 1. A casing 26 is arranged in the interior 24 of the housing 25 and essentially completely surrounds or encapsulates the beam path in the illumination optical unit 4, as described in U.S. Pat. No. 8,382,301 B2 or in U.S. Pat. No. 8,585,224 B2 for example, which are incorporated into this application in their entirety by reference. The casing 26 is a vacuum housing which is composed of multiple partial housings and consists essentially of stainless steel in the example shown. Such a partial housing is depicted as representative in FIG. 2; it encapsulates a portion of the beam path between the first facet mirror 20 and the second facet mirror 22 and is referred to as casing 26 below. In order to simplify the illustration, the remainder of the illumination optical unit 4 has not been shown in FIG. 2.

A residual gas 27 with hydrogen as the main constituent is contained both in the interior 24 of the housing 25 and in the casing 26. The pressure p of the residual gas 27 in the interior 24 corresponds to the hydrogen partial pressure and is in the order of between approx. 1 Pa and 20 Pa, for example between approx. 2 Pa and approx. 12 Pa. The pressure p of the residual gas 27 within the casing 26 is also in the specified pressure range.

Contaminating substances 28 are found both in the vacuum environment in the interior 24 outside of the casing 26 and within the casing 26. The volume within the casing 26 is typically purged by with a purge gas, such that there is generally a smaller amount of contaminating substances 28 (indicated by dots in FIG. 2) within the casing 26 than outside the casing 26. For example, the contaminating substances 28 can arise if a component arranged in the vacuum environment comes into contact with hydrogen, especially with activated hydrogen. The activated hydrogen is formed from the molecular hydrogen present in the residual gas 27 of the vacuum environment in the interior 24 by an interaction with the illuminating radiation or EUV radiation 16.

The contaminating substances 28 that outgas from such a component are typically what are called HIO elements or HIO compounds, for example compounds containing phosphorus, zinc, tin, sulfur, indium, magnesium or silicon. Should the contaminating substances 28 reach the optical surfaces of the two facet mirrors 20, 22, they are deposited on the surfaces of the facet mirrors 20, 22, more precisely on the first facets 21 and, respectively, the second facets 23, and reduce the transmission thereof. The HIO compounds deposited on the surfaces can be removed only with great difficulty, if at all, from the surfaces of the facet mirrors 20, 22.

A plurality of gas-binding components 29 are fitted to the casing 26 in the vicinity of a respective facet mirror 20, 22 in order to make sure that as little of the contaminating substances 28 as possible reaches the surfaces of the facet mirrors 20, 22. The part cut illustration of FIG. 2 shows three respective gas-binding components 29 arranged in the vicinity of the first facet mirror 20 and three more arranged in the vicinity of the second facet mirror 22. The gas-binding components 29 shown in FIG. 2 have the same embodiment and each comprise a planar mount 30, to which a plurality of planar component portions 31 have been fitted.

As may be easily identified in the gas-binding component 29 shown in FIG. 3A, the planar component portions 31, embodied in the form of sheets 31′ in the example shown in FIG. 3A, are aligned in parallel and fastened one above the other to the lateral mount 30, with adjacent sheets 31′ having the same spacing from one another. In the example shown, the sheets 31′ consist of stainless steel and comprise a coating (not depicted pictorially) consisting of (at least) one gas-binding material on both sides. The gas-binding material in the example shown is a material selected from the group comprising: Ru, Ni, NiP, Rd, Rh, Ta, Nb, Ti, Zr, Th and the compounds thereof. This and other, especially metallic, materials or alloys, enable binding of the or a majority of the contaminating substances 28 present in the interior 24 of the housing 25 of the projection exposure apparatus 1 or present in the residual gas 27.

A flow duct 33 is formed between in each case two adjacent sheets 31′. In the case of the equidistantly spaced-apart sheets 31′, a respective flow duct 33 has an identical flow width h, which corresponds to the distance between the two adjacent sheets 31′. The flow duct 33 formed between the sheets 31′ is open on three sides and delimited on the fourth side by the lateral mount 30. This is possible because the sheets 31′ have a sufficient inherent stiffness for a one-sided mount. Depending on the thickness of the sheets 31′, support structures, for example in the form of support struts or the like, may be fitted to the gas-binding component 29 in order to prevent the sheets 31′ from sagging. As a rule, the sheets 31′ have only a small thickness, on the order of approx. 1 millimeter in order to prevent an excessive weight of the sheets 31′ and hence of the entire gas-binding component 29.

FIG. 3B shows a gas-binding component 29′, in which the planar component portions 31 are in the form of films 31″, which are clamped between two lateral mounts 30a, 30b aligned in the vertical direction. The films 31″ are also provided in double-sided fashion with a coating made of a gas-binding material on their top side and on the bottom side. A flow duct 33 is formed in each case between a surface 32a on the top side of a respective lower film 31″ and a surface 32b on the bottom side of a respectively adjacent upper film 31″, and said flow duct has a flow width h corresponding to the distance between adjacent films 31″ or between the surfaces 32a, 32b. As evident from FIG. 3B, a respective flow duct 33 is open on two opposing sides and is delimited on the two other sides by the lateral mounts 30a, 30b. If only little residual gas 27 reaches the two open sides of the respective flow duct 33 for installation space reasons, then there may be the option of providing openings in the films 31″ which enable or facilitate inflow of the residual gas 27 into the flow ducts 33. It is possible that the surfaces 32a, 32b are structured, e.g., by roughening or by any other type of substructure, in order to increase the effective surface or increase the capture probability for the contaminating substances 28.

In the examples shown in FIG. 2 and in FIGS. 3A, 3B, the flow width h of a respective flow duct 33 is matched to the mean free path length l̅ so that a Knudsen flow is present, i.e., so that the following applies to the Knudsen number Kn denoting the ratio between the mean free path length l̅ and the flow width h (i.e., Kn=l̅/h):

$$0.01 < K n < 5 , preferably 0.01 < K n < 0.5 ,$$

$$most preferably 0.01 < K n < 0.3 .$$

As explained below on the basis of FIGS. 4A-4C, the presence of a Knudsen flow in the flow duct 33 is advantageous for the application described herein, in which as many of the contaminating substances 28 as possible are intended to be adsorbed at the surfaces 32a, 32b of a respective flow duct 33.

FIG. 4A shows the flow duct 33 when a gas flow in the form of a continuum flow (Kn<0.01) is present; FIG. 4B shows said flow duct in the presence of a Knudsen flow (i.e., 0.01<Kn<5); and FIG. 4C shows said flow duct in the presence of a molecular flow (Kn>5). As evident from FIG. 4A, there are frequent collisions among the gas particles and a penetration or a diffusion into the flow duct 33 when a continuum flow of the residual gas 27 is present; however, there are only infrequent collisions with the walls of the flow duct 33. There is practically no more interaction among the gas particles in the case of the molecular flow of the residual gas 27 shown in FIG. 4C. The gas particles strike the walls of the flow duct 33 frequently but there no longer is transport into the flow duct 33.

In the case of the Knudsen flow shown in FIG. 4B there firstly is sufficient diffusion for the gas flow of the residual gas 27 to penetrate deeply into the flow duct 33, and there secondly are sufficient interactions with the walls of the flow duct 33 so that the contaminating substances 28 can be adsorbed by the gas-binding material on the wall or on the walls of the flow duct 33. The gas-binding component thus acts in the style of an atomic trap for the contaminating substances 28, which enter the flow duct 33 and are bound by the gas-binding material on the surfaces 32a, 32b. This applies both to the gas-binding component 29 with the plurality of sheets 31′, shown in FIG. 3A, and to the gas-binding component 29′ with the plurality of films 31″, shown in FIG. 3B.

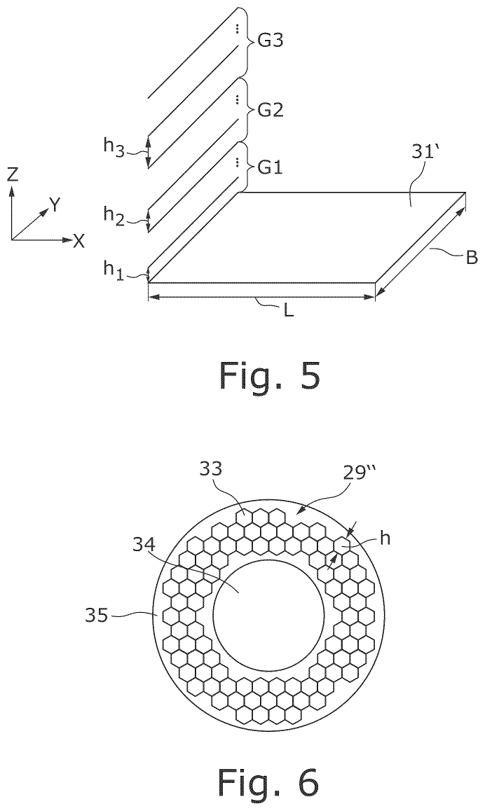

FIG. 5 shows an example for the dimensioning of a gas-binding component 29, 29′ shown in FIGS. 3A, 3B, more precisely for dimensions and for distances or for different flow widths h₁, h₂, h₃ between the planar component portions 31, which may be in the form of sheets 31′ or in the form of films 31″. It is assumed hereinafter that the planar component portions are sheets 31′. In the example shown, a respective sheet 31′ has a length L of approx. 43 cm and a width B of approx. 41 cm. In this case, the length L corresponds to the length of a respective flow duct 33.

In the case of the arrangement shown in FIG. 5, a first group G1 of sheets 31′ is arranged at distances h₁ of approx. 5 mm in each case, a second group G2 of sheets 31′ is arranged at distances h₂ of approx. 10 mm in each case, and a third group G3 of sheets 31′ is arranged at distances h₃ between one another of approx. 20 mm in each case. To simplify the illustration, FIG. 5 only shows the lowermost of the sheets 31′. Each of the three groups G1, G2, G3 may have a different number of sheets 31′. If the intention is for all three groups G1, G2, G3 to have approximately the same volume or the same extent in the height direction Z of an XYZ-coordinate system, then it is advantageous in the case of the above-described dimensioning if the first group G1 has more sheets 31′ than the second group G2, and the second group G2 has more sheets than the third group G3.

The provision of different flow widths h₁, h₂, h₃, . . . is advantageous since different contaminating substances 28 in each case have different effective cross sections with the hydrogen contained in the residual gas 27. The flow width h₁, h₂, h₃, . . . is therefore adjusted for a respective type of contaminating substance 28.

It is understood that the flow ducts 33 need not necessarily extend between two planar component portions 31; instead, any desired geometries of the flow channels 33 are possible as a matter of principle. In particular, the flow channels 33 can be closed in the circumferential direction. FIG. 6 shows an example of a gas-binding component 29″ which comprises such flow ducts 33 with a cross section in the shape of a regular hexagon. In the example shown there, a plurality of flow ducts 33 are arranged adjacent to one another in the style of honeycombs. In the example shown in FIG. 6, the gas-binding component 29″ surrounds an optical surface 34 of the first facet mirror 20 in ring-shaped fashion. The gas-binding component 29″ is fitted to a mount 35 to which the first facet mirror 20 has also been fastened. The end of a respective flow channel 33 facing the mount 35 is spaced apart from the mount 35 in order to allow residual gas 27 to emerge from the respective flow channel 33. The gas-binding components 29 depicted in FIG. 2 are arranged accordingly, i.e., they are fastened to the mount 35 of the respective facet mirror 20, 22.

A gas-binding component designed like the component 29″ shown in FIG. 6 also allows the flow width h to be adjusted for a respective contaminating substance 28. For example, a plurality of planar components embodied like the component 29″ shown in FIG. 6 can be arranged one above the other for this purpose. The flow width h of the regular hexagons 33 of a respective planar component is chosen differently in each case here and is adjusted for the type of contaminating substance 28 intended to be bound.

It is understood that a respective gas-binding component 29, 29′, 29″ can also be arranged at a different location to in the vicinity of a respective facet mirror 20, 22. For example, in the example shown in FIG. 3A, the gas-binding component 29 is fitted to a maintenance shaft 36 of the casing 26 shown in FIG. 2. The maintenance shaft 36 adjoins a lateral opening 37 in the wall of the casing 26 and extends outwardly therefrom into the interior 24 of the housing 25. The gas-binding component 29 is integrated into the maintenance shaft 36 in the example shown in FIG. 3A; more precisely, the mount 30 of the gas-binding component 29 forms the front plate or the lid of an insert used to seal the maintenance shaft 26. The insert with the gas-binding component 29 can be taken from the maintenance shaft 36 with the aid of a handle 38 fitted to the front plate or the mount 30. This is advantageous in order to allow an exchange of the gas-binding component 29 if the gas-binding material no longer has a sufficient uptake capacity for the contaminating substances 28. Unlike what is shown in FIG. 2, the planar component portions 31 can also extend over the entire height of the maintenance shaft 36. The planar component portions 31 can optionally also partly protrude through the opening 37 into the casing 26, albeit not into the beam path of the projection exposure apparatus 1.

It is understood that one or more gas-binding components 29, 29′, 29″ can also be arranged at a different location in the projection exposure apparatus 1, with an arrangement both within the casing 26 and outside of the casing 26 being possible. The flow duct or ducts 33 of a respective gas-binding component may also be fitted in the style of, e.g., cylindrically symmetrical fins or the like to rod-shaped elements. Moreover, additional, suitably shaped sheets or plates can optionally serve as gas-binding components which, optionally together with a wall of the casing 26 or with other walls provided in the projection exposure apparatus 1, form a flow duct 33 that satisfies the Knudsen flow conditions described further above.

The above description of embodiments has been given by way of example. From the disclosure given, those skilled in the art will not only understand the present invention and its attendant advantages but will also find apparent various changes and modifications to the structures and methods disclosed. The applicant seeks, therefore, to cover all such changes and modifications as fall within the spirit and scope of the invention, as defined by the appended claims, and equivalents thereof.

What is claimed is:

1. An extreme ultraviolet (EUV) lithography system comprising:
a housing having an interior which contains a residual gas, and
at least one gas-binding component which is arranged in the interior and which comprises a gas-binding material for binding contaminating substances,
wherein the gas-binding component comprises at least one flow duct having at least one surface with the gas-binding material, wherein a gas flow of the residual gas in the flow duct has a Knudsen number of between 0.01 and 5, and wherein a casing which encapsulates a beam path of the EUV lithography system is arranged in the interior of the housing.

2. The EUV lithography system as claimed in claim 1, wherein the gas flow of the residual gas in the flow duct has a Knudsen number of between 0.01 and 0.3.

3. The EUV lithography system as claimed in claim 1, wherein the casing comprises an opening with a maintenance shaft in which the gas-binding component is arranged.

4. The EUV lithography system as claimed in claim 1, wherein the residual gas in the interior of the housing has a pressure of between 1 Pa and 20 Pa.

5. The EUV lithography system as claimed in claim 4, wherein the residual gas in the interior of the housing has a pressure of between 2 Pa and 12 Pa.

6. The EUV lithography system as claimed in claim 1, wherein the flow duct has a flow width of between 1 mm and 30 mm.

7. The EUV lithography system as claimed in claim 1, wherein the flow duct has a flow width of between 4 mm and 20 mm.

8. The EUV lithography system as claimed in claim 1, wherein the flow duct comprises two opposing surfaces, the surfaces each having the gas-binding material, with a distance between the opposing surfaces defining a flow width of the flow duct.

9. The EUV lithography system as claimed in claim 8, wherein the two opposing surfaces are aligned in parallel and are formed on two planar component portions.

10. The EUV lithography system as claimed in claim 9, wherein the planar component portions are formed as sheets or as films.

11. The EUV lithography system as claimed in claim 1, wherein the flow duct has a cross section formed as a a regular polygon.

12. The EUV lithography system as claimed in claim 11, wherein the flow duct has a cross section formed as a a regular hexagon.

13. The EUV lithography system as claimed in claim 1, wherein the gas-binding component has a plurality of flow ducts with mutually differently dimensioned flow widths for binding mutually differing contaminating substances.

14. The EUV lithography system as claimed in claim 1, wherein the flow duct has a length of at least 20 cm.

15. The EUV lithography system as claimed in claim 14, wherein the flow duct has a length of at least 40 cm.

16. The EUV lithography system as claimed in claim 1, wherein the gas-binding material is selected from the group consisting essentially of: Ru, Ni, NiP, Rd, Rh, Ta, Nb, Ti, Zr, and Th, and compounds of Ru, Ni, NiP, Rd, Rh, Ta, Nb, Ti, Zr, and Th.

17. The EUV lithography system as claimed in claim 1, wherein the at least one surface with the gas-binding material is structured.

18. The EUV lithography system as claimed in claim 1, further comprising at least one reflective optical element arranged in the interior of the housing, wherein the gas-binding component is arranged adjacent to the reflective optical element.

19. The EUV lithography system as claimed in claim 18, wherein the gas-binding component is arranged at least partly surrounding a surface of the reflective optical element.
